(19) United States
(12) Patent Application Publication
(10) Pub. No.: US 2011/0128794 A1
(43) Pub. Date: Jun. 2, 2011

(54) APPARATUS AND METHOD FOR CONTROLLING OPERATION TIMING IN SEMICONDUCTOR MEMORY DEVICE

(76) Inventors: Hyun-Su Yoon, Gyeonggi-do (KR); Jong-Chern Lee, Gyeonggi-do (KR)

(21) Appl. No.: 12/649,021

(22) Filed: Dec. 29, 2009

(30) Foreign Application Priority Data
Nov. 30, 2009 (KR) 10-2009-0117422

(51) Int. Cl. G11C 7/10; G11C 7/00

(52) U.S. Cl. 365/189.05; 365/194; 365/189.12

(57) ABSTRACT

An apparatus for controlling an operation timing in a semiconductor memory device, comprising: a shift information generator configured to generate shift information based on data path delay information and latency information; and a shift register configured to shift a command based on the shift information and produce a shifted command to control an operation timing.

### CROSS-REFERENCE TO RELATED APPLICATIONS

The present application claims priority of Korean Patent Application No. 10-2009-0117422, filed on Nov. 30, 2009, which is incorporated herein by reference in its entirety.

### BACKGROUND OF THE INVENTION

Exemplary embodiments of the present invention relate to a semiconductor device, and more particularly, to an apparatus and method for controlling an operation timing in a semiconductor memory device.

In general, when a write command is inputted to a semiconductor memory device, such as Double Data Rate 3 Dynamic Random Access Memory (DDR3 DRAM), a write operation should be performed in synchronization with a clock based on dynamic on-die termination (DODT). Also, when an on-die termination (ODT) command is inputted to the semiconductor memory device, an ODT operation is performed in synchronization with a clock based on normal ODT. Also, when a read data is inputted to the semiconductor memory device, a data output operation should be performed in synchronization with a clock based on the same CAS (Column Address Strobe) write latency (CWL) and read latency (RL), which are determined by a mode register set (MRS). Herein, the read latency may be represented by a summation of an additive latency (AL) and a CAS latency (CL).

In particular, the ODT operation and a read operation in a DRAM are performed in synchronization with as many clocks as the number of the read latency or CAS write latency. To this end, in order to perform a corresponding operation at a timing that conforms to Joint Electron Device Engineering Council (JEDEC) from the moment when a write/read/ODT command is inputted, the corresponding command is delayed to be in synchronization with an external clock based on a read latency or CAS write latency inside the DRAM, regardless of operation frequency or other conditions.

Korean Patent No. 625298 discloses a technology that can determine an enable time of an ODT circuit based on latency information. The Korean Patent No. 625298 suggests a technology in which an external clock counting signal and a Delay Locked Loop (DLL) clock counting signal are compared with each other and controlled. According to the technology, since a semiconductor memory device occupies a significant area and requires a continuous counting operation, a great deal of power is consumed.

While a semiconductor memory device is driven in synchronization with a signal, it is divided into a plurality of domains based on the signal with which another signal is synchronized, which will be simply referred to as a sync signal hereafter. Therefore, when data is to be transferred from a first domain to a second domain, a process of synchronizing a data of the first region with a signal to be synchronized for the second region is required. Herein, the process for transferring a data of a first region to a second region where the first region and the second region have a different sync signal is referred to as a domain crossing process. In other words, the domain crossing process is a process of synchronizing a data output enable signal, which is synchronized with an internal clock, with a clock of a delay locked loop.

Since the domain crossing process has a delay, when a data output enable signal is outputted in synchronization with a clock, it becomes difficult to perform a control at an exact activation time as the operation frequency of a semiconductor memory device grows faster. To cope with the operation frequency of the semiconductor device, the domain crossing method requires an area for a domain crossing block to be secured in the semiconductor memory device. Therefore, there is a spatial limitation in terms of designing of a semiconductor memory device.

### SUMMARY OF THE INVENTION

Exemplary embodiments of the present invention are directed to an apparatus for controlling the timing of a termination operation in a semiconductor memory device based on shift information for a shift register generated from data path delay information and latency information, and a method thereof.

In accordance with an embodiment of the present invention, an apparatus for controlling an operation timing in a semiconductor memory device, comprising: a shift information generator configured to generate shift information based on data path delay information and latency information; and a shift register configured to shift a command based on the shift information and produce a shifted command to control an operation timing.

In accordance with another embodiment of the present invention, an apparatus for controlling an operation timing in a semiconductor memory device, comprising: a shift information generator configured to generate shift information based on data path delay information and latency information; a delayer configured to delay a command; and a shift register configured to shift a delayed command based on the shift information and produce a shifted command to control an operation timing.

In accordance with yet another embodiment of the present invention, A method for controlling an operation timing in a semiconductor memory device, comprising: generating shift information based on data path delay information and latency information; and shifting a command based on the shift information and produce a shifted command to control an operation timing.

In accordance with still another embodiment of the present invention, a method for controlling an operation timing in a semiconductor memory device, comprising: generating shift information based on data path delay information and latency information; delaying a command; and shifting a delayed command based on the shift information and produce a shifted command to control an operation timing.

### BRIEF DESCRIPTION OF THE DRAWINGS

FIG. 1 is a diagram illustrating an operation timing controlling apparatus of a semiconductor memory device in accordance with an embodiment of the present invention.

FIGS. 2A and 2B illustrate exemplary embodiments of a shift register shown in FIG. 1.

FIG. 3 is a diagram illustrating a process for determining an on-die termination (ODT) timing.

FIG. 4 is a block diagram describing an operation timing controlling apparatus of a semiconductor memory device in accordance with another embodiment of the present invention.

FIG. 5 is a flowchart describing a method for controlling a latency timing in the semiconductor memory device shown in FIG. 1.

FIG. 6 is a flowchart describing a method for controlling a latency timing in the semiconductor memory device shown in FIG. 4.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments.

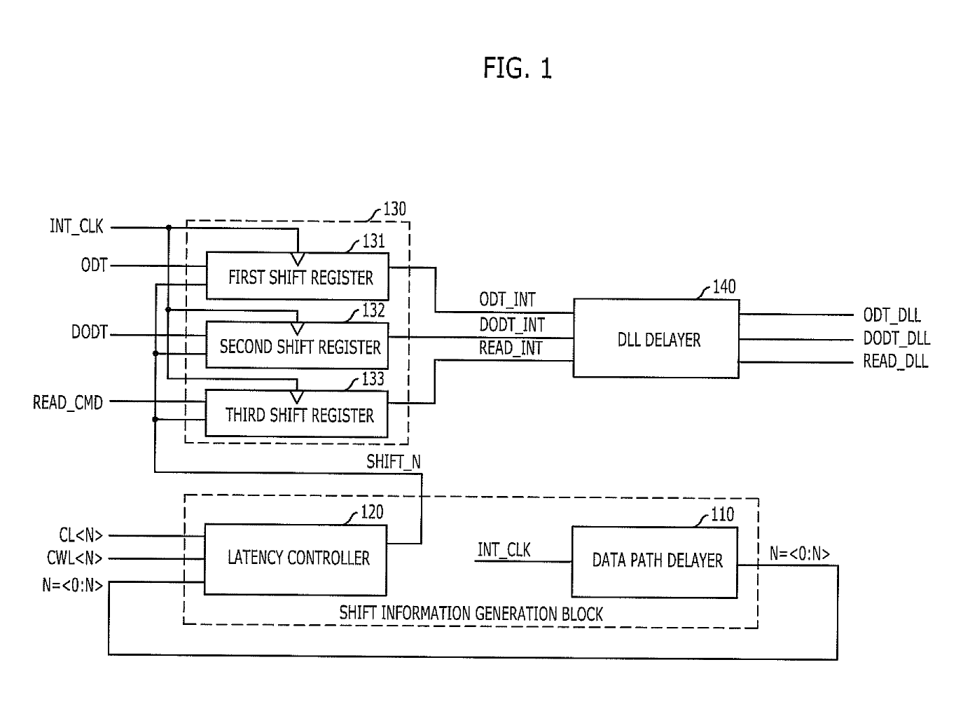

FIG. 1 is a diagram illustrating an operation timing controlling apparatus of a semiconductor memory device in accordance with an embodiment of the present invention. When any one of an on-die termination (ODT) command, a dynamic on-die termination (DODT) command, and a read command is inputted, the operation timing controlling apparatus of a semiconductor memory device controls an operation timing by delaying the corresponding command in synchronization with an external clock so that the semiconductor memory device, such as Double Data Rate 3 Dynamic Random Access Memory (DDR3 DRAM), operates based on a latency timing that conforms to Joint Electron Device Engineering Council (JEDEC) Specification.

To this end, the operation timing controlling apparatus generates and provides shift information for a shift register based on data path delay information that is confirmed through a data path modeling (e.g., clock number information) and latency information set to a mode register set (MRS) (e.g., CAS latency (CL), or CAS write latency (CWL)), so as to determine how long it will delay the corresponding command. In other words, the operation timing controlling apparatus performs a control to operate the semiconductor memory device based on the timing of each termination, such as dynamic termination, normal termination, and data output operation, which is determined as described above.

Referring to FIG. 1, the operation timing controlling apparatus includes a data path delayer 110, a latency controller 120, a shift register 130, and a Delay Locked Loop (DLL) delayer 140. In this embodiment, the data path delayer 110 interlocks with the latency controller 120 to generate shift information for the shift register 130. For the sake of convenience in description, the combination of the data path delayer 110 and the latency controller 120 is referred to as a shift information generation block, hereafter. The shift information generation block generates shift information, which is information on how much a corresponding command is to be shifted in the shift register 130, and provides the generated shift information to the shift register 130.

In addition, the data path delayer 110 and the DLL delayer 140 form a DLL block (not shown), and the latency controller 120 and the shift register 130 form a control block (not shown). Herein, the control block controls an internal clock INT_CLK based on a command and it operates only when a command is inputted.

Hereafter, the constituent elements of the operation timing controlling apparatus will be described in more detail.

First, the data path delayer 110 includes a delay circuit formed by modeling a data path for figuring out the extent of physical delay when a corresponding command is processed through a data path inside a semiconductor memory device. The purpose of the modeling is to reflect the extent of delay occurring in the data path into the latency of the corresponding command so that the corresponding command operates at a time that conforms to JEDEC. Accordingly, the data path delayer 110 checks data path delay information (i.e., a clock number information N, which is the extent of the delay for the corresponding command), and provides the data path delay information to the latency controller 120. Accordingly, the data path delayer 110 pre-calculates and keeps clock number information ‘N,’ which is needed in the initial period of an operation. Thus, as compared with the conventional technology, the control block operates in a close relationship with a DLL block. Since the same effect is provided without a continuous counting operation, which was essential in the conventional technology, the semiconductor memory device consumes a less amount of power. In addition, since the semiconductor memory device does not require a plurality of control blocks, the area can be reduced.

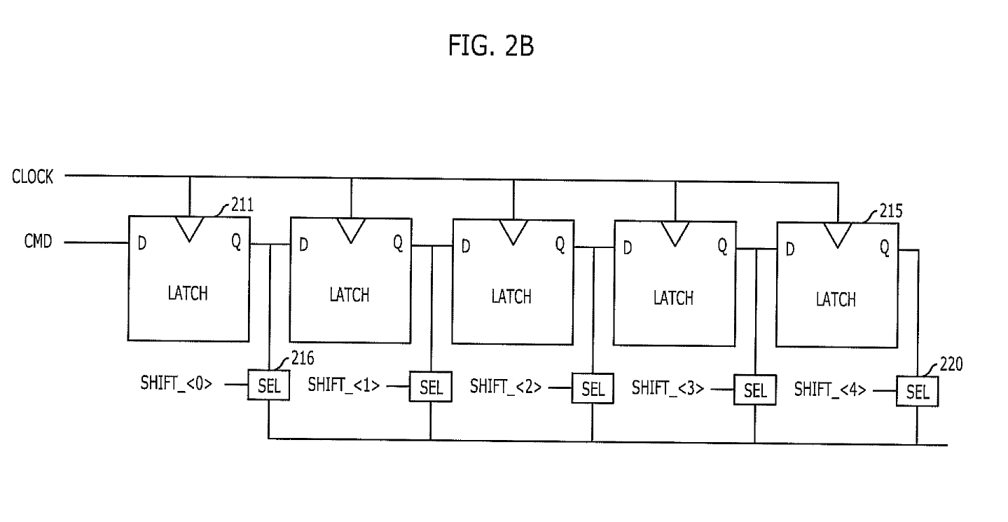

Additionally, the latency controller 120 generates shift information SHIFT_N, which indicates to what extent the corresponding command is to be shifted in the shift register 130, and transfers the shift information SHIFT_N to the shift register 130. The latency controller 120 generates the shift information SHIFT_N based on latency information logically needed for the corresponding command, which is CAS latency or CAS write latency, and data path delay information, which is the extent of a delay occurring when the corresponding command physically passes through a data path. Herein, the latency information, which is a CAS latency or CAS write latency, is provided by a mode register set, and the data path delay information is provided by the data path delayer 110. To be specific, the latency controller 120 selects a CAS latency or CAS write latency based on a termination operation, and generates the shift information SHIFT_N by subtracting the data path delay information provided by the data path delayer 110 from a selected value (see FIG. 3). Therefore, the latency controller 120 may be implemented using logical operators, such as a full adder or a subtractor.

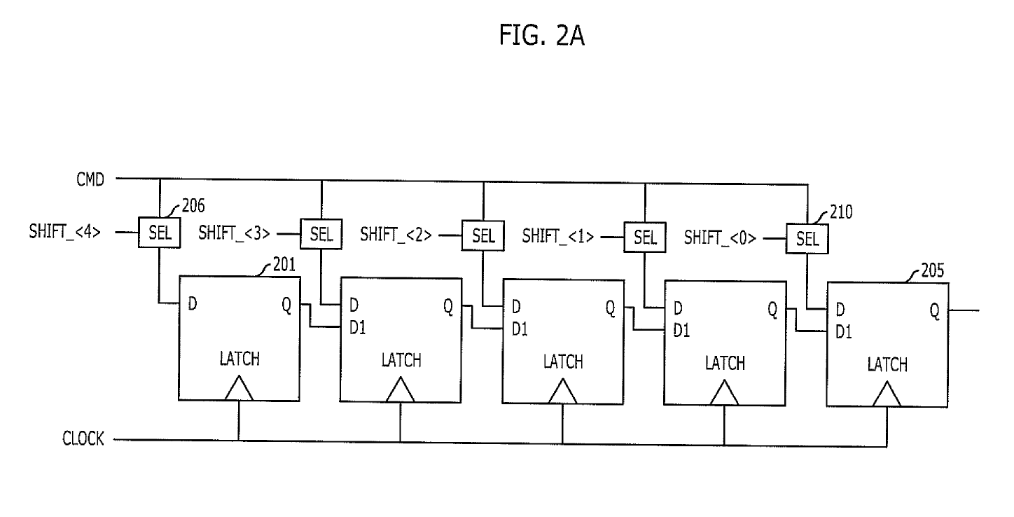

Furthermore, the shift register 130 generates a command ODT_INT, DODT_INT, and READ_INT obtained by shifting an ODT command, a write command, and a read command in response to the number of clocks of the shift information SHIFT_N provided by the latency controller 120. Herein, the internal clock INT_CLK applied to the shift register 130 is generated and provided only when the ODT command, the write command, or the read command is inputted. Detailed structure of the shift register 130 will be described later with reference to FIGS. 2A and 2B. Herein, the shift register 130 collectively refers to registers each of which delays a corresponding command in response to the number of clocks of the shift information SHIFT_N. In one embodiment, the shift register 130 includes a first shift register 131, a second shift register 132, and a third shift register 133. In short, the first shift register 131 delays the ODT command in response to the number of clocks of the shift information SHIFT_N, and the second shift register 132 delays the write command in response to the number of clocks of the shift information SHIFT_N. Further, the third shift register 133 delays the read command in response to the number of clocks of the shift information SHIFT N. In FIG. 1, the ODT command corresponds to “ODT,” and the write command corresponds to “DODT,” while the read command corresponds to “READ_CMD.”

Moreover, the DLL delayer 140 generates commands ODT_DLL, DODT_DLL, and READ_DLL whose domain is changed into a DLL_CLK domain, which will be referred to as domain-changed commands hereafter, from the shifted commands ODT_INT, DODT_INT, and READ_INT produced by the shift register 130. Since this process may be easily understood by those skilled in the art capable of understand a typical DLL operation, further description of the process will not be provided herein. The DLL delayer 140 transfers the domain-changed commands ODT_DLL, DODT_DLL, and READ_DLL through the data path so that operations are controlled to be performed at desired times.

FIGS. 2A and 2B illustrate exemplary embodiments of a shift register 130 shown in FIG. 1. Referring to FIG. 2A, a corresponding command is shifted by controlling an input based on the shift information SHIFT_N transferred from the latency controller 120. Herein, the shift register 130 positions one or more latches coupled in series, and the same clock is applied to each of the latches. Herein, the shift register 130 receives the shift information SHIFT_N transferred from the latency controller 120, and selects a latch corresponding to the shift information SHIFT_N so that a command is inputted to the selected latch. Then, the command sequentially passes through the other latches coupled to the selected latch to thereby shift and output the command.

In FIG. 2A, when the shift information SHIFT_N is SHIFT_<4>, the shift register 130 is controlled to select (see 206) a latch 201 into which the corresponding command is inputted first. Subsequently, the corresponding command sequentially passes through each of the latches coupled to the latch 201 until the corresponding command reaches the last latch 205. As a result of passing through each of the latches 201 to 205, the corresponding command is shifted to an extent corresponding to the shift information SHIFT_<4>. Herein, the corresponding command passes through a total of 5 latches from the latch 201 where the corresponding command is inputted first to the last latch 205, and is outputted in a shifted state. Conversely, when the shift information SHIFT_N is SHIFT_<0>, the shift register 130 is controlled to select (see 210) the latch 205 into which the corresponding command is inputted first. Because the latch 205 is the last latch, the corresponding command does not pass through any other latches. Herein, the corresponding command passes through only the last latch 205, and is outputted in a shifted state.

Referring to FIG. 2B, a corresponding command is shifted by controlling an output based on the shift information SHIFT_N of the shift register 130 transferred from the latency controller 120.

As shown in FIG. 2A, the shift register 130 positions one or more latches coupled in series, and applies the same clock to each of the latches.

Herein, the shift register 130 receives the shift information SHIFT_N transferred from the latency controller 120, and selects any one of the commands each of which is already shifted through each latch, and outputs the selected command. In other words, the shift register 130 sequentially passes the corresponding command through the latches from a latch 211 into which the corresponding command is inputted first to the last latch 215. The latches 211 to 215 store the corresponding commands of different shifted states according to the respective latches. Thus, the shift register 130 can output a corresponding command of a shifted state acquired based on the shift information SHIFT_N.

For example, in FIG. 2B, when the shift information SHIFT_N is SHIFT_<0>, the shift register 130 selects (see 216) a latch 211 into which the corresponding command is inputted first and provides a command outputted from the latch 211 into which the corresponding command is inputted first. The corresponding command is shifted only by the corresponding latch 211 and outputted therefrom. Likewise, when the shift information SHIFT_N is SHIFT_<4> in FIG. 2B, the shift register 130 selects (see 220) the latch 215 into which the corresponding command is inputted last and provides a command outputted from the latch 215. Herein, the corresponding command passes through a total of 5 latches from the latch 211 where the corresponding command is inputted first to the last latch 215 and outputted in a shifted state.

As described above, the shift register 130 may be implemented as shown in FIG. 2A where a command is shifted by controlling an input, or as shown in FIG. 2B where a command is shifted by controlling an output. In the case of FIG. 2A where an input is controlled, once shift information SHIFT_N is determined, the corresponding command passes through the latch and then a shift process is performed. On the other hand, in the case of FIG. 2B where an outputted is controlled, all the shifted commands that can be outputted during a shifting process are prepared. Then, once shift information SHIFT_N is determined, a corresponding shifted command is outputted among all the shifted commands. Therefore, the case where an input is controlled as shown in FIG. 2A has a slow shifting process, compared with the case where an output is controlled as shown in FIG. 2B. However, since not all the latches operate in the case of FIG. 2A, there is an advantage in that the device deterioration is slow.

FIG. 3 is a diagram illustrating a process for determining an on-die termination (ODT) timing. In FIG. 3, for example, when an ODT command is inputted, clock number information, which is data path delay information, is calculated to be ‘1’ by the data path delayer 110, and CAS write latency is set at ‘5,’ the latency controller 120 determines the shift information SHIFT_N to be ‘2.’ In short, shift information SHIFT_N=(CAS write latency−2)−data path delay information.

The shift register 130 shifts the ODT command based on the shift information SHIFT_N transferred from the latency controller 120. Therefore, in the above example, since the shift information SHIFT_N is ‘2,’ the shift register 130 shifts the ODT command by two clocks, and outputs a shifted command ODT_INT.

Subsequently, the DLL delayer 140 delays the ODT_INT through a DLL circuit to thereby produce a domain-changed command ODT_DLL, and controls a timing so that a termination operation is performed at a time desired by DQs, which is CAS write latency −2, herein.

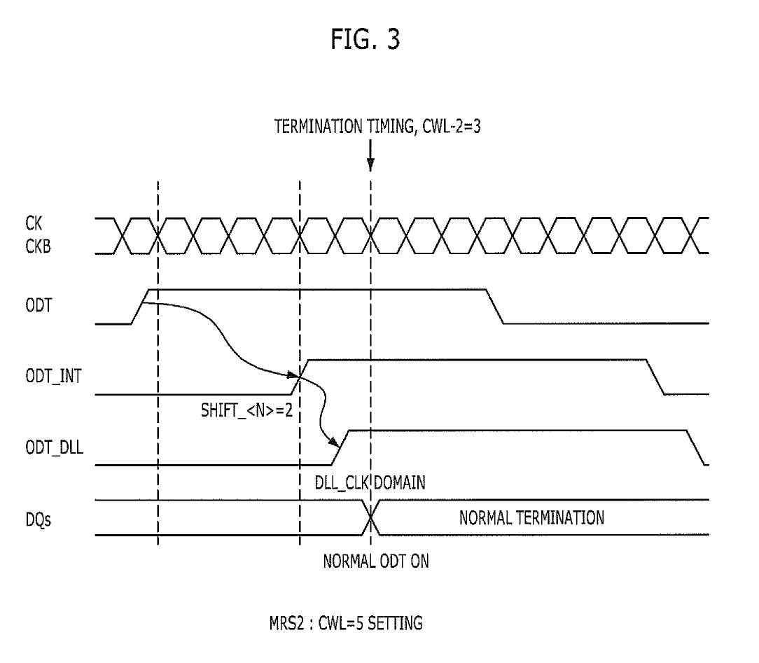

FIG. 4 is a block diagram describing an operation timing controlling apparatus of a semiconductor memory device in accordance with another embodiment of the present invention.

In the embodiment of the operation timing controlling apparatus described above, the corresponding command is shifted by an internal clock INT_CLK and a domain is changed based on DLL_CLK. However, according to this embodiment shown in FIG. 4, a corresponding command goes through a domain change based on DLL_CLK, and then the corresponding command is shifted based on shift information SHIFT_N.

In the embodiment of FIG. 4, the constituent elements of the operation timing controlling apparatus correspond to those appearing in FIG. 1. However, for the sake of convenience in description, the constituent elements of FIG. 4 are given different reference numerals. According to this embodiment shown in FIG. 4, the operation timing controlling apparatus includes a data path delayer 410, a latency controller 420, a shift register 430, and a DLL delayer 440. Since the constituent elements shown in FIG. 4 correspond to the constituent elements shown in FIG. 1, a detailed description of them will be omitted herein.

First, the data path delayer 410 provides data path delay information to the latency controller 420. The latency controller 420 generates shift information SHIFT_N based on the data path delay information (e.g., clock number information) and latency information set in a mode register set (e.g., CAS latency or CAS write latency). In other words, a shift information generation block performs the same function shown in FIG. 1.

Further, the present embodiment shown in FIG. 4 has the following features. The DLL delayer 440 changes the domain of an ODT command, a write command, and a read command into a DLL_CLK domain and then inputs the domain-changed commands and internal clock to the shift register 430. The ODT command corresponds to ‘ODT,’ and the write command corresponds to ‘DODT,’ while the read command corresponds to ‘READ_CMD.’ Herein, the shift register 430 shifts the domain-changed commands produced by the DLL delayer 440 and outputs shifted commands based on the shift information SHIFT_N, transferred from the latency controller 420, and the internal clock, whose domain is changed by the DLL delayer 440.

Herein, as illustrated in FIG. 1, the shift register 430 collectively refers to registers each of which delays a corresponding command in response to the number of clocks of the shift information SHIFT_N. In one embodiment, the shift register 430 includes a first shift register 431, a second shift register 432, and a third shift register 433. In short, the first shift register 431 delays the ODT command whose domain is changed in response to the number of clocks of the shift information SHIFT_N, and the second shift register 432 delays the write command whose domain is changed in response to the number of clocks of the shift information SHIFT_N. The third shift register 433 delays the read command whose domain is changed in response to the number of clocks of the shift information SHIFT_N.

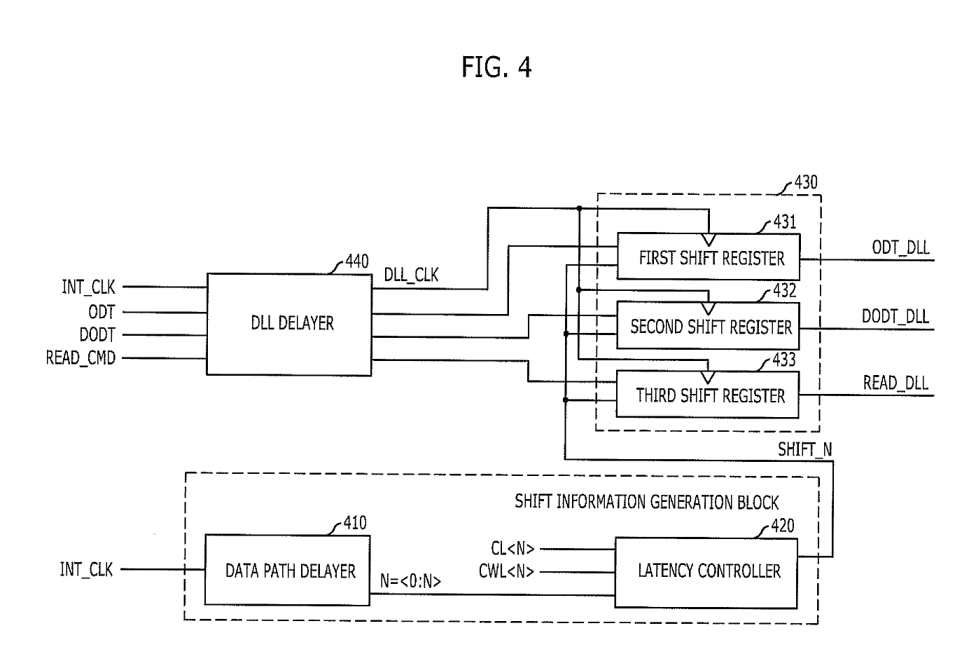

FIG. 5 is a flowchart describing a method for controlling a latency timing in the semiconductor memory device shown in FIG. 1. First, in step S501, the shift information generation block generates shift information based on data path delay information (e.g., clock number information) and latency information (e.g., CAS latency or CAS write latency).

In step S502, the shift register 130 shifts a corresponding command based on the shift information. In step S503, the DLL delayer 140 delays the corresponding command transferred from the shift register 130 through a DLL circuit. Through this process, the operation timing controlling apparatus can control a timing needed for a termination operation.

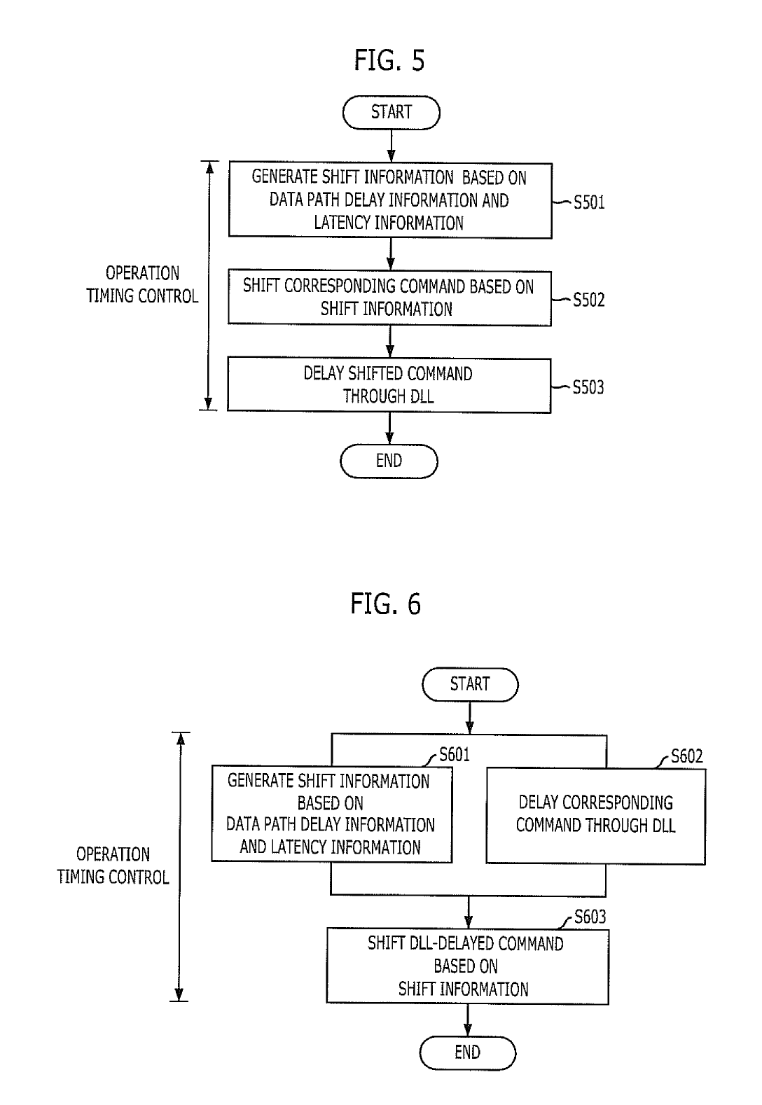

FIG. 6 is a flowchart describing a method for controlling a latency timing in the semiconductor memory device shown in FIG. 4. First, in step S601, the shift information generation block generates shift information based on data path delay information (e.g., clock number information) and latency information (e.g., CAS latency or CAS write latency).

Simultaneously, in step S602, the DLL delayer 440 delays a corresponding command through a DLL to thereby produce a DLL-delayed corresponding command. Herein, the DLL delayer 440 delays an internal clock needed to shift the corresponding command through the DLL and provides the DLL-delayed internal clock.

Subsequently, in step S603, the shift register 430 shifts the DLL-delayed corresponding command based on the shift information. Through this process, the operation timing controlling apparatus can control a timing needed for a termination operation.

According to the embodiments of the present invention, a corresponding command is shifted based on shift information, which is generated based on data path delay information and latency information, and delays the corresponding command through a DLL to thereby control a timing for a termination operation.

Also, according to the embodiments of the present invention, since the data path delay information is calculated in advance in the initial period of an operation of a semiconductor memory device, it does not have to perform a continuous counting operation. As a result, power consumption is reduced and since control blocks, which used to be necessary in conventional technology, are removed, the area of the semiconductor memory device may be decreased.

Also, according to the embodiments of the present invention, although an area to be occupied by domain crossing blocks is not secured in a semiconductor memory device, it is still possible to control an operation timing.

While the present invention has been described with respect to the specific embodiments, it will be apparent to those skilled in the art that various changes and modifications may be made without departing from the spirit and scope of the invention as defined in the following claims.

What is claimed is:

1. An apparatus for controlling an operation timing in a semiconductor memory device, comprising:
a shift information generator configured to generate shift information based on data path delay information and latency information; and
a shift register configured to shift a command based on the shift information and produce a shifted command to control an operation timing.

2. The apparatus of claim 1, further comprising:
a delayer configured to delay and output the shifted command.

3. The apparatus of claim 1, wherein the shift information generator includes:
a data path delayer configured to calculate a delay extent by modeling a data path and output the calculated delay extent as the data path delay information; and
a latency controller configured to generate the shift information using the latency information needed for the command from a mode register set and the data path delay information, and output the shift information.

4. The apparatus of claim 3, wherein the data path delay information is clock number information, and
the latency information is determined to be any one between CAS(Column Address Strobe) latency or CAS write latency based on the command.

5. The apparatus of claim 1, wherein the shift register comprises;
a plurality of latches connected in sequence; and
a selecting unit configured to receive the command, and select one of the latches based on the shift information and output the received command to the selected latch.

6. The apparatus of claim 1, wherein the shift register comprises;
a plurality of latches connected in sequence, and configured to receive and latch the command; and
a selecting unit configured to select one of the latches based on the shift information so as for the selected latch to output a corresponding command.

7. The apparatus of claim 1, wherein the register operates in response to an internal clock inputted, as the command is inputted.

8. An apparatus for controlling an operation timing in a semiconductor memory device, comprising:
a shift information generator configured to generate shift information based on data path delay information and latency information;
a delayer configured to delay a command; and
a shift register configured to shift a delayed command based on the shift information and produce a shifted command to control an operation timing.

9. The apparatus of claim 8, wherein the shift information generator includes:
a data path delayer configured to calculate a delay extent by modeling a data path and output the calculated delay extent as the data path delay information; and
a latency controller configured to generate the shift information using the latency information needed for a command from a mode register set and the data path delay information, and output the shift information.

10. The apparatus of claim 9, wherein the data path delay information is clock number information, and
the latency information is determined to be any one between CAS latency or CAS write latency based on the command.

11. The apparatus of claim 8, wherein the shift register comprises;
a plurality of latches connected in sequence; and
a selecting unit configured to receive the delayed command, and select one of the latches based on the shift information and output the delayed command to the selected latch.

12. The apparatus of claim 8, wherein the shift register comprises;
a plurality of latches connected in sequence, and configured to receive and latch the delayed command; and
a selecting unit configured to select one of the latches based on the shift information so as for the selected latch to output a corresponding command.

13. The apparatus of claim 8, wherein the register operates in response to an internal clock inputted, as a command is inputted.

14. A method for controlling an operation timing in a semiconductor memory device, comprising:
generating shift information based on data path delay information and latency information; and
shifting a command based on the shift information and produce a shifted command to control an operation timing.

15. The method of claim 14, further comprising:
delaying and outputting the shifted command.

16. The method of claim 14, wherein a data path delay information is calculated a delay extent by modeling a data path; and
the latency information is provided from a mode register set based on the command.

17. The method of claim 16, wherein the data path delay information is clock number information, and
the latency information is determined to be any one between CAS latency or CAS write latency based on the command.

18. A method for controlling an operation timing in a semiconductor memory device, comprising:
generating shift information based on data path delay information and latency information;
delaying a command; and
shifting a delayed command based on the shift information and produce a shifted command to control an operation timing.

19. The method of claim 18, wherein a data path delay information is calculated a delay extent by modeling a data path; and
the latency information is provided from a mode register set based on the command.

20. The method of claim 19, wherein the data path delay information is clock number information, and
the latency information is determined to be any one between CAS latency or CAS write latency based on the command.
